(19) United States
(12) Patent Application Publication
(10) Pub. No.: US 2014/0226285 A1
(43) Pub. Date: Aug. 14, 2014

(54) Component and Method for Producing a Component

(71) Applicants: Christian Bauer, Muenchen (DE); Hans Krueger, Muenchen (DE); Juergen Portmann, Muenchen (DE); Alois Stelzl, Muenchen (DE); Alexander Schmajew, Muenchen (DE)

(72) Inventors: Christian Bauer, Muenchen (DE); Hans Krueger, Muenchen (DE); Juergen Portmann, Muenchen (DE); Alois Stelzl, Muenchen (DE); Alexander Schmajew, Muenchen (DE)

(73) Assignee: EPCOS AG, Muenchen (DE)

(21) Appl. No.: 14/239,990

(22) PCT Filed: Aug. 10, 2012
(86) PCT No.: PCT/EP2012/065759

§ 371 Date: Apr. 15, 2014

(30) Foreign Application Priority Data
Sep. 5, 2011 (DE) 10 2011 112 476.8

(51) Int. Cl. H05K 5/06

(52) U.S. Cl. CPC H05K 5/066
USPC 361/736; 228/256; 228/261; 228/259; 228/176

(57) ABSTRACT

A component includes a substrate, a chip, and a frame. The frame, the substrate, and the chip enclose a volume. A metal sealing layer is provided which is designed to hermetically seal the volume. The metal sealing layer has a hardened liquid metal or a hardened liquid metal alloy.

This patent application is a national phase filing under section 371 of PCT/EP2012/065759, filed Aug. 10, 2012, which claims the priority of German patent application 10 2011 112 476.8, filed Sep. 5, 2011, each of which is incorporated herein by reference in its entirety.

### TECHNICAL FIELD

Embodiments of the present invention relate to components and methods of making components.

### BACKGROUND

Components of the microelectromechanical system (MEMS), microelectro-optical system (MEOPS) or microelectro-optomechanical system (MEOMS) type comprise a chip, which has functional carriers connected to interconnects and is mounted on a carrier substrate. Such chips are generally positioned by flip-chip technology and encapsulated for protection against environmental influences, such as temperature, moisture and electromagnetic radiation.

In order to encapsulate the components, for example, a jet or spray technology based on polymers is used. These technologies, however, have the disadvantage that the polymers use to degas under thermal stress and are not hermetic against gas diffusion, and in particular water vapor diffusion. For hermetic sealing of the encapsulation, inter alia, metal nanoparticles are also used with subsequent electrolytic reinforcement of the encapsulation. Nanoparticles, and in this case particularly metal nanoparticles, are stabilized before a sintering step by jet printing with an organic film which only decomposes at elevated temperatures. Even under standard conditions, and particularly under thermal stress, organic material can emerge and thus contaminate the interior of the encapsulated component.

If metal layers deposited from a plasma jet are used for sealing the components, these layers comprise micropores and without further measures the encapsulation is not hermetic. Furthermore, although methods such as chip-to-substrate bonding, which are derived from wafer-to-wafer bonding or chip-to-wafer bonding, are possible, they are technologically very elaborate.

### SUMMARY OF THE INVENTION

Embodiments of the present invention provide a component and a method for producing a component, which allow improved hermetic sealing.

In one embodiment, the component comprises a substrate, a chip and a frame. In this case, the frame, the substrate and the chip enclose a volume. A metal sealing layer is provided and is adapted in order to seal the volume hermetically and electromagnetically.

Preferably, the substrate is gas-tight and comprises a ceramic, such as a high-temperature multilayer ceramic or HTCC (high-temperature cofired ceramic) or a low-temperature burn-in ceramic or LTCC (low-temperature cofired ceramic). Depending on the requirements, sufficiently gas-tight polymers with low water vapor absorption and degassing are also suitable, for example substrates with LCP interlayers (LCP=liquid-crystal polymer) or substrates whose surface is passivated. It is furthermore preferred for the chip to comprise quartz, lithium tantalate, lithium niobate or similar substances and functional elements, for example, transducers for surface acoustic waves or bulk acoustic waves. To this end, for example, it has a piezoelectric material, electroacoustic transducers and suitable interconnects.

The metal sealing layer is applied onto the component in the form of a liquid metal or a liquid metal alloy. The metal or the metal alloy subsequently solidifies and forms hermetic encapsulation. This encapsulation may then optionally be electrolytically reinforced.

No organic solvents or polymers are necessary for application of the metal sealing layer. Furthermore, advantageously, no pores or micropores are formed in the sealing layer during the solidification, which is preferably carried out under controlled conditions. The component is therefore protected against contamination.

At least two different structural variants are possible for the component.

In one embodiment, the frame is connected to the substrate. The chip bears only on the frame. The frame preferably has a planar surface, for example, smoothed by means of diamond milling. In this way, it is possible for a chip provided with bump connections to bear uniformly on the frame after flip-chip mounting and collapsing of the bump connections in a subsequent reflow process and, with correspondingly adapted frame heights, bump connection heights and collapsing, for a gap between the chip and the frame to be almost zero. By applying pressure to the chip with molten bump connections and cooling below the melting point of the bumps with constant pressure application, the gap between the chip and the frame can be minimized and, in the case of diamond-milled frames, can be less than 10 nm.

The metal sealing layer is applied along the gap between the chip and the frame, and correspondingly extends along this gap. The connection of the chip and the frame, and therefore the encapsulation of the component, is carried out by the liquid metal or the liquid metal alloy solidifying.

In this structural variant, a large-area substrate (for example, of HTCC, LTCC or PCB made of LCP) is provided with a multiplicity of frames in a first method step. Over these frames, in a further method step, bumped chips are placed in flip-chip technology and electrically and mechanically connected to the substrate by means of the bumps in a reflow process. After encapsulation of the chips, the substrate with the chips is divided along suitable sawing tracks to form components.

In another embodiment, or an alternative structural variant, the frame is connected to the chip. After placement on the substrate, the frame bears on or forms a gap with a width of up to a few μm. The width of the gap may vary locally. This variation may, if need be, be limited upward by planarizing the frame or the substrate.

The metal sealing layer is applied along a gap, which extends between the substrate and the frame. By solidification of the liquid metal or the liquid metal alloy, a connection is established between the substrate and the frame.

So that the metal sealing layer can connect to the substrate, an appropriate pretreatment of the substrate (for example, pre-structuring) may be necessary.

In this alternative structural variant, each chip carries a frame. The need for a pretreatment of the substrate depends on the sealing layer used. Opposite the bumped chips, the substrate has a metallization layer in the form of an underbump metallization, and it also carries electrically conductive structures. During production of the substrate, frame structures, for example, wettable by solder, may be applied onto the substrate for the metallization layer.

According to another embodiment, the substrate, the chip, the frame and the metal sealing layer are at least partially enclosed by an electrolytically deposited layer.

With the aid of the electrolytically deposited layer, the metal sealing layer can be further reinforced. The metal sealing layer is used as a crystallization seed layer for the subsequent electrolytic deposition.

In another embodiment, the metal sealing layer constitutes a jet structure and is produced by jet printing according to data.

In order to form the jet structure, the metal sealing layer, or the liquid metal or the liquid metal alloy, is applied with the aid of a jet method. In this way, a high positional accuracy can be achieved and the metal sealing layer can be applied along the respective gap in the different structural variants.

In another embodiment, the metal sealing layer constitutes a solder structure.

With the aid of the solder structure, the liquid metal or the liquid metal alloy can be applied first as a solder depot without the need for direct contact with the corresponding gap in the various structural variants. In order to activate the metal sealing layer, the solder structure is preferably heated so that parts of the liquid metal or the liquid metal alloy enter the gap and can seal the latter by solidifying.

In another embodiment, the chip is electrically and mechanically interconnected with the substrate on a surface inclined toward the enclosed volume by at least one bump connection, in particular a stud bump or solder bump.

In another embodiment, the frame comprises a metal or a multilayer structure of metals.

The frame on the substrate is preferably made of copper, nickel, silver or a multilayer structure of these metals, and connected gas-tightly to the substrate or the chip.

The use of metals or multilayer structures of metals is advantageous because these wet either directly or by means of chemical functionalization with the liquid metal or the liquid metal alloy of the metal sealing layer.

Other materials for the frame, for example, ceramic or glass solder, may likewise be envisaged. These materials can be applied selectively, for example, by the “rapid prototyping” method by laser sintering according to data.

In another embodiment, the liquid metal or the liquid metal alloy for forming the metal sealing layer comprises metals with melting points Smp of less than 300° C. under standard conditions.

Suitable examples include: AuSn (Smp=283° C.), Sn (Smp=231° C.), SnAg, SnCu, SnAgCu, 90In10Ag (Smp=237° C.), In (Smp=157° C.), 97In3Ag (Smp=143° C.), 52In48Sn (Smp=118° C.), 42Sn58Bi (Smp=138° C.), SnBi, SnBiAg, SnZn.

According to another embodiment, the liquid metal or the liquid metal alloy for forming the metal sealing layer comprises metals which, although they wet the chip and the substrate, do not flow on the chip or the substrate. In this case, for example, In is suitable because it wets both the chip and ceramic.

In another embodiment, the component is produced by one of the following methods.

In one embodiment of a method for producing a component having a substrate, a chip and a frame, the following steps are provided. First, a volume is enclosed by means of the frame, the substrate and the chip. Lastly the volume is hermetically sealed with a metal sealing layer by sealing the gap between the frame and the chip, or between the frame and the substrate, with a liquid metal or a liquid metal alloy. The metal or metal alloy subsequently solidifies. The metal sealing layer thus forms hermetic encapsulation. Subsequently, this encapsulation may optionally be electrolytically reinforced.

No organic solvents or polymers are necessary for application of the metal sealing layer. Furthermore, advantageously, no pores or micropores are formed in the sealing layer during the solidification, which is preferably carried out under controlled conditions. The component is therefore protected against contamination and other environmental influences.

In another embodiment, the frame is connected to the substrate. The chip bears only on the frame. The metal sealing layer is applied along a gap between the chip and the frame. The chip and the frame are connected by solidification of the liquid metal or the liquid metal alloy.

In another embodiment, the frame is connected to the chip. The frame bears partially on the substrate and/or forms a gap of a few μm with respect thereto. The metal sealing layer is applied along a gap between the substrate and the frame. The substrate is connected to the frame by solidification of the liquid metal or the liquid metal alloy.

The liquid metal or the liquid metal alloy may be applied by the following methods: by jet printing of solder materials, by spraying of solder materials, and/or by immersion of the substrate equipped with chips in a liquid solder bath. The excess solder can be removed by blowing, for example, by means of N₂, in a similar way as in the “hot air leveling” method.

### BRIEF DESCRIPTION OF THE DRAWINGS

The invention will be explained below with reference to several exemplary embodiments with the aid of figures. Where parts or components correspond in their function, the description thereof will not be repeated for each of the following figures.

FIGS. 1A, 1B and 1C respectively show exemplary embodiments of a component according to the proposed principle; and

FIGS. 2A, 2B, 2C and 2D show exemplary embodiments of a component in a first structural variant with different metal sealing layers according to the proposed principle.

### DETAILED DESCRIPTION OF ILLUSTRATIVE EMBODIMENTS

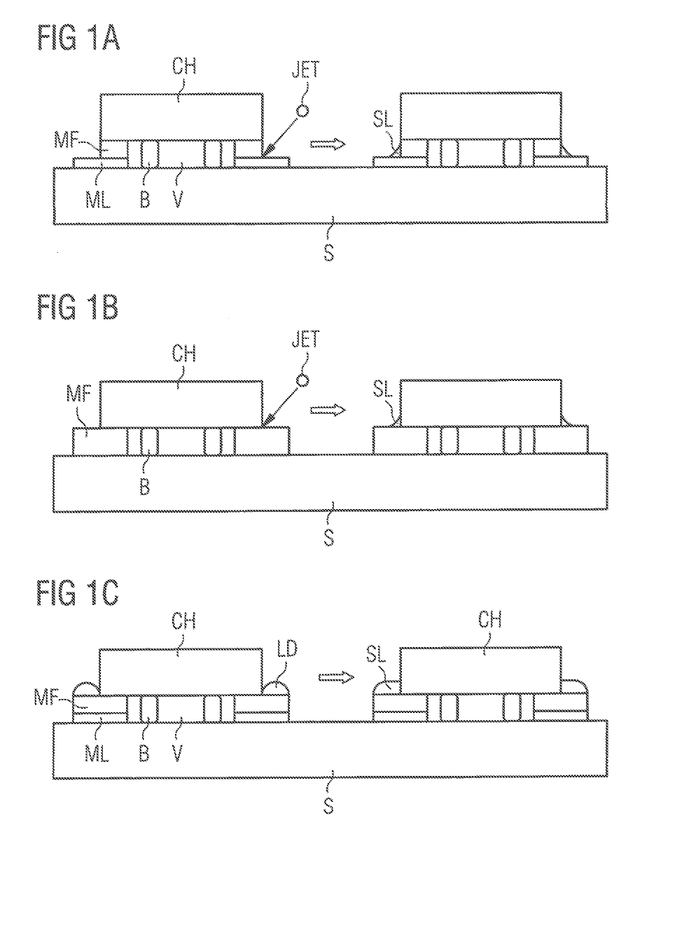

FIGS. 1A to 1C respectively show a component during (left-hand component) and after (right-hand component) the respective production method of a sealing layer. FIG. 1A shows a first exemplary embodiment of a component according to the proposed principle. A first structural variant in flip-chip technology is shown. Therein, a metal frame MF is applied on a chip CH so that the metal frame MF partially bears on a substrate S or forms a gap of up to a few μm with respect to the substrate. The metal frame MF may consist of a material such as Cu, or of a sequence of different metals. The chip CH is connected electrically and mechanically to the substrate S by means of bump connections B. To this end, for example, solder bumps or stud bumps are used.

The gap between the metal frame and the chip is determined by the accuracy of the production processes of the frame and by the planarity of the substrate in the respective frame region. By planar milling of the metal frame, it is possible to achieve a frame surface planar in the sub-μm range. Likewise, if necessary, the substrate may be planarized. The maximum permissible gap for achieving a hermetic seal depends essentially on the amount of jet metal applied, for example on the amount of solder. A droplet of the liquid jet metal during the jet printing is represented by JET.

FIG. 1B shows an exemplary embodiment of a component according to the proposed principle in a second structural variant in flip-chip technology. In this case, the metal frame MF is connected to the substrate S. The metal frame MF may consist of a material such as Cu, or of a sequence of different metals. The chip CH is connected electrically and mechanically to the substrate S by means of bump connections B. To this end, for example, solder bumps or stud bumps or Cu/Sn pillars are used.

In contrast to the first structural variant, in the second structural variant the chip CH bears partially on the metal frame MF or forms a sufficiently small gap with the metal frame. The substrate S, metal frame MF and chip CH again contain a volume V.

The comments below may be applied to both structural variants according to FIGS. 1A and 1B. If differences are necessary, these will be mentioned explicitly.

In order to seal the volume V hermetically and vacuum-tightly, a metal sealing layer SL is applied onto the component by a jet technology. To this end, a liquid metal or a liquid metal alloy is applied onto the component along the gap SP and thus forms the metal sealing layer SL. The gap SP between the metal frame MF and the substrate S, or between the metal frame MF and the chip CH, is therefore sealed by solidified jet-printed metal. Depending on whether the metal frame lies on the chip or on the substrate, jet metals which also form a firm bond with the substrate or the side faces of the chip are particularly suitable. For both alternatives, for example, this is the case for In.

As an alternative, according to FIG. 1C, metal solder depots LD may be jet-printed onto the metal frame MF and soldered before further process steps. By wetting the adjoining metal faces of the metal frame MF and of the wettable side faces of the chip CH, the metal sealing layer SL is developed and the component is hermetically sealed. Such soldering may, for example, take place in a reflow oven or in a plasma system with or without the action of an oxide-reducing gas (example: forming gas) or a plasma. The wettability may be ensured by applying a wettable layer during a previous method stage.

The jet printing of liquid metal or liquid metal alloys is carried out at an angle which is dictated according to the topology of the substrate S. In another case, when producing solder depots which, as described above, wet the metal frame MF in the subsequent reflow process and then seal the component, the jet printing may be carried out at the technologically simpler right angle with respect to the surface, or the substrate plane, since direct contact of the solder depot LD with the chip sides or frame sides is not absolutely necessary in this method (see FIG. 1C).

No organic solvents or polymers are necessary for application of the metal sealing layer. Furthermore, advantageously, no pores or micropores are formed in the sealing layer during the solidification, which is preferably carried out under controlled conditions. The component is therefore protected against contamination and other environmental influences.

The liquid metal or the liquid metal alloy, or the solder depot, for forming the metal sealing layer SL comprises metals with melting points Smp of less than 300° C. under standard conditions. Suitable examples include: AuSn (Smp=283° C.), Sn (Smp=231° C.), SnAg, SnCu, SnAgCu, 90In10Ag (Smp=237° C.), In (Smp=157° C.), 97In3Ag (Smp=143° C.), 52In48Sn (Smp=118° C.), 42Sn58Bi (Smp=138° C.), SnBi, SnBiAg, SnZn.

So that, when jet printing liquid metal or liquid metal alloys, and when jet printing solder depots, the chips CH remain in position even during further wetting processes, bump connections B are necessary, the melting points Smp of which preferably satisfy the following relations:

Smp (bump)>Smp (jet metal)

T (during jet printing)<Smp (bump).

This condition is always satisfied for Au or Cu(Pt) stud bumps when solder is used as liquid metal. Thermal expansion coefficients are adapted to one another.

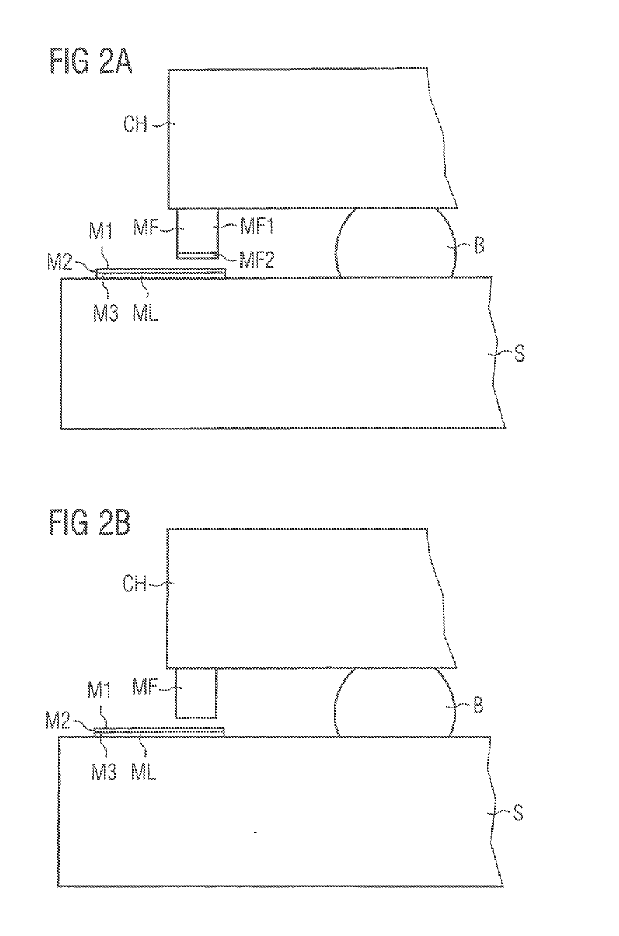

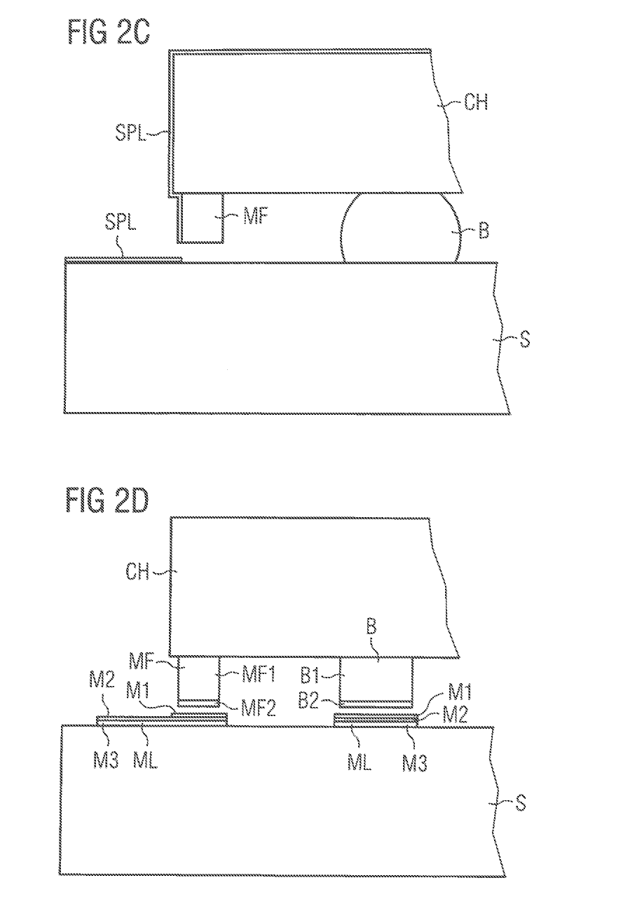

FIGS. 2A, 2B, 2C and 2D show exemplary embodiments of a component according to the first structural variant with different configurations according to the proposed principle. The first structural variant will be used by way of example; unless otherwise mentioned, the principles presented can also be applied to a component according to the second structural variant.

In FIG. 2A, the metal frame MF comprises a layer sequence of first and second metals MF1, MF2. In this case, the second metal MF2 is applied in a thin layer onto the first metal MF1. The second metal comprises, for example, Ag, Au, Pd, Pt or Sn, and is composed in such a way that it is wetted by the liquid jet metal. The metal frame MF may in this case be provided with the thin layer fully or only on its upwardly (downwardly) facing surface. This layer is preferably deposited electrolessly, and has a thickness of less than 1 μm when it consists of Ag, Au, Pd or Pt, and a thickness of preferably about 100 nm in the case of Au, Pd and Pt.

The metallization layer ML on the substrate S likewise comprises different materials M1, M2, M3 in layer form. The metallization layer ML is applied onto the substrate S in the course of the production thereof, and likewise has a frame structure. For example, when using HTCC, the metallization layer ML may consist of a layer sequence M1, M2, M3. These may for instance comprise W, Ni and Au. When LTCC is used as the ceramic, the layer sequence M1, M2, M3 may, for example, comprise Ag, Cu and Pd. The metallization layer ML is produced by depositing the respective materials and optionally sintering them. The thickness of the metallization layer ML is in this case dependent on the topology of the substrate S, and is selected in such a way that it can be milled flat before the chip or chips CH is or are applied.

As an alternative, the metallization layer ML may be deformable and, for example, made of Sn.

FIG. 2B shows a similar structure which, in contrast to the embodiment according to FIG. 2A, does not have a thin layer of a second metal MF2 on the metal frame MF.

FIG. 2C shows an embodiment in which a metal layer SPL or metal layer sequence is applied over the substrate S equipped with chips CH and the chips CH before the jet printing. This metal layer may, for example, comprise Au, Ag, Pt, Pd, Cu, TiCu, TiWCu, TiCuAu, TiCuAg. The metal layer SPL is composed in such a way that it is wetted by the liquid jet metal. The layer SPL is applied by a PVD method or, preferably, by sputtering, for example, in a low-temperature plasma method.

In FIG. 2D, for example, the bump connection B is formed by a layer sequence consisting of a first and a second bump material B1, B2. In this case, in a similar way as for the metal frame MF represented in FIG. 2A, the second bump material B2 is applied in a thin layer on the first bump material B1. The second bump material is for example Ag, Au, Pd, Sn or Pt, and is composed in such a way that it is wetted by the liquid jet metal. This facilitates soldering of the bump connection to the substrate S by means of the metallization layer ML. To this end, the metallization layer ML again comprises the layer sequence M1, M2, M3.

In another embodiment of the invention (not shown), the metal sealing layer may also be produced by immersing the substrate S equipped with chips CH in a liquid solder. This is expediently carried out in a form of wave solder method. The excess solder may then be blown off in a hot air leveling method, or spun off. In this embodiment as well, it is advantageous for the temperature of the solder in the bath to be lower than the melting temperature of the bump connections B.

1-15. (canceled)

16. A component comprising:
a substrate;
a chip;
a frame, the frame, the substrate and the chip enclosing a volume; and
a metal sealing layer which hermetically seals the volume, the metal sealing layer comprising a solidified liquid metal or a solidified liquid metal alloy.

17. The component according to claim 16,
wherein the frame is connected to the substrate and the chip bears on the frame; and
wherein the metal sealing layer extends along a gap between the chip and the frame and connects the chip and the frame.

18. The component according to claim 16,
wherein the frame is connected to the chip and the frame bears on the substrate; and
wherein the metal sealing layer extends along a gap between the substrate and the frame and connects the substrate and the frame.

19. The component according to claim 16, wherein the substrate, the chip, the frame and the metal sealing layer are at least partially enclosed by an electrolytically deposited layer.

20. The component according to claim 16, wherein the metal sealing layer constitutes a jet printing structure.

21. The component according to claim 16, wherein the metal sealing layer comprises a solder structure.

22. The component according to claim 16, wherein the chip is interconnected with the substrate on a surface inclined toward the enclosed volume by at least one bump connection.

23. The component according to claim 16, wherein the at least one bump connection comprises a stud bump or solder bump.

24. The component according to claim 16, wherein the frame comprises a metal or a multilayer structure of metals.

25. The component according to claim 16, wherein the liquid metal or the liquid metal alloy for forming the metal sealing layer by solidification comprises metals with melting points of less than 300° C. under standard conditions.

26. The component according to claim 16, wherein the liquid metal or the liquid metal alloy for forming the metal sealing layer comprises metals of a nonzero wettability with the surface of the chip and/or of the substrate.

27. A method for producing a component having a substrate, a chip and a frame, the method comprising:
enclosing a volume between the frame, the substrate and the chip; and
hermetically sealing the volume with a metal sealing layer by applying a liquid metal or a liquid metal alloy onto the component and solidifying the liquid metal or the liquid metal alloy.

28. The method according to claim 27,
wherein the frame is connected to the substrate and the chip bears on the frame; and
wherein the metal sealing layer is applied along a gap between the chip and the frame and connects the chip and the frame by solidification of the liquid metal or the liquid metal alloy.

29. The method according to claim 27, wherein
the frame is connected to the chip and the frame bears on the substrate; and
the metal sealing layer is applied along a gap between the substrate and the frame and connects the substrate and the frame by solidification of the liquid metal or the liquid metal alloy.

30. The method according to claim 27, wherein the liquid metal or the liquid metal alloy is applied by dosing with a jet printing technique.

31. The method according to claim 27, wherein the liquid metal or the liquid metal alloy is applied by applying a solder depot and heating the solder depot.

32. The method according to claim 27, wherein the liquid metal or the liquid metal alloy is applied by at least partially immersing the component in a liquid solder.

33. The method according to claim 27, wherein the liquid metal or liquid metal alloy has a melting point of less than 300° C.

34. The method according to claim 27, further comprising electrolytically deposits a layer over the metal sealing layer.

35. The method according to claim 27, wherein the liquid metal or liquid metal alloy comprises a solder.
